(19) United States
(12) Patent Application Publication
(10) Pub. No.: US 2025/0042309 A1
(43) Pub. Date: Feb. 6, 2025

(54) Seat Cover Having a Control Element, Seat Element for a Motor Vehicle, and Motor Vehicle

(71) Applicant: Bayerische Motoren Werke Aktiengesellschaft, Muenchen (DE)

(72) Inventor: Matthias OESTERREICH, Muenchen (DE)

(21) Appl. No.: 18/717,007

(22) PCT Filed: Jan. 24, 2023
(86) PCT No.: PCT/EP2023/051602

§ 371 Date: Jun. 6, 2024

(30) Foreign Application Priority Data
Feb. 21, 2022 (DE) 10 2022 104 005.4

(51) Int. Cl. B60N 2/02; B60N 2/58; B60N 2/72; H03K 17/96

(52) U.S. Cl. CPC B60N 2/0228; B60N 2/5816; B60N 2/72; H03K 17/962; H03K 2217/96062

(57) ABSTRACT

A seat cover for a seat element of a motor vehicle has an electronic control element having a touch-sensitive sensor surface, which control element is designed to be coupled to a control device of the motor vehicle for controlling a vehicle function. Owing to an actuating action which a user performs on an outer surface portion of a predetermined actuation portion of the seat cover, as a result of which the touch-sensitive sensor surface is actuated, the control element is designed to provide a control signal, wherein the actuation portion and a remaining portion of the seat cover are connected to one another without gaps.

### BACKGROUND AND SUMMARY

The present invention relates to a seat cover for a seat element of a motor vehicle, wherein the seat cover comprises an electronic control element. The invention furthermore relates to a seat element for a motor vehicle of this type, wherein the seat element comprises a seat body which is covered by a seat cover of this type. The motor vehicle is, in particular, a motor vehicle comprising a saddle seat system, that is to say, for example, for a motorcycle, an ATV (all-terrain vehicle or “quad”), etc. The control element can be used to control one vehicle function or a multiplicity of vehicle functions by virtue of an actuating action on/with the control element being performed by a (human) user of the seat element, for example a driver or passenger of the motor vehicle equipped with the seat element. In addition, the invention relates to a motor vehicle, in particular a motorcycle, with a seat element of this type.

Seat heaters for motor vehicles are known, for example from DE 196 39 750 A1 or from DE 10 2004 034 675 A1. In the motorbike sector, for example, a rider's seat heater can be switched on/switched off, switched over and/or controlled by the rider using an operator control element arranged in the region of the motorbike handlebar, for example a seat heater switch, and/or using a corresponding control command input into a vehicle operator control system, which is based on a selection menu, in the region of an instrument cluster. Such operator control elements are known, for example, from DE 10 2017 212 064 A1 or from DE 10 2016 203 194 A1. There are motorcycle models in which a pillion passenger seat heater does not have their own assigned operator control element; instead, the operator control element of the pillion passenger seat heater is located in the region of the motorbike handlebar, and therefore only the rider has access to it in the riding mode. In this case, the pillion passenger therefore has no option for switching the pillion passenger seat heater without having to distract the rider. This is because the pillion passenger has to make the rider aware of them to then make their desire clear that the seat heater should be operated, so that the rider can then adjust the pillion passenger seat heater. Furthermore, it is known to arrange an operator control element for controlling the pillion passenger seat heater in a region accessible to the pillion passenger. A conventional seat heater operator control element may be, for example, a mechanical rocker switch which, by means of its latching positions, characterizes the switch position and therefore the heating stage.

Conventionally, such seat heater operator control elements are connected to a seat pan of the corresponding seat by means of an operator control element support, with an actuating element of the operator control element jutting out from a cover of the seat and penetrating the latter. As a result, there is a gap between the operator control element and the cover, with there nowadays being an attempt to close or to cover the gap by means of additional panels. Such panels fit esthetically only poorly into an overall appearance of the seat and consequently of the corresponding vehicle. Furthermore, such a construction has a particularly large number of parts which have to be connected to one another to produce the seat. Furthermore, it may be the case that a liquid, for example rainwater, undesirably penetrates or runs through the gap into the interior of the seat and damages the vehicle there. Furthermore, the seat is harder at least at the location of the operator control element or the panel, and therefore it may be the case that a user of the seat is forced into an uncomfortable sitting position to avoid butting with a body part against the panel.

It is the object of the invention to provide a possibility of integrating an operator control element for controlling a vehicle function particularly efficiently into a seat system of the vehicle.

This object is achieved by the subjects of the independent claims. Further possible refinements of the invention are disclosed in the dependent claims, the description and the figures. Features, advantages and possible refinements which are presented within the scope of the description for one of the subjects of the independent claims should be considered at least analogously as features, advantages and possible refinements of the respective subject matter of the other independent claims and of any possible combination of the subjects of the independent claims, optionally in combination with one or more of the subclaims.

The invention proposes a seat cover for a seat element. In the position fitted as intended, the seat element has the seat cover by virtue of a seat body of the seat element being covered by the seat cover. The seat element is designed here for use in/on a motor vehicle. Accordingly, the motor vehicle, when it is finished or produced ready for use, has the seat cover by virtue of the motor vehicle having the seat element. The motor vehicle is, in particular, a motor vehicle with a saddle seat system, for instance a motorcycle or motorbike or another (possibly unmotorized) vehicle which has such a saddle seat system. In addition, the seat cover or the seat element having the seat cover is suitable for use in/on other vehicles, such as cars.

The seat cover comprises an electronic control element which is an operator control element which can be used by a user, for example the driver/rider or passenger/pillion passenger, of the motor vehicle/motorcycle to control one vehicle function or a multiplicity of vehicle functions. This means that the electronic control element is designed (that is to say arranged and configured) to be coupled to a control device of the motor vehicle in order to control a vehicle function. The electronic control element, that is to say the seat cover, comprises a touch-sensitive sensor surface-similar to that of a touchpad. The touch-sensitive sensor surface is thus, for example, a resistive and/or capacitive sensor surface.

The seat cover, whose entire outer surface forms, among other things, a seat surface on which the user can sit in the position fitted as intended, comprises an actuation portion. The entire outer surface of the seat cover is thus formed of a first outer surface portion of the actuation portion and a further or second outer surface portion of a non-actuation portion different or separate from the actuation portion. In this case, at least some of the sensor surface of the control element is functionally assigned to the actuation portion or the outer surface portion thereof. The control element is thus designed, owing to an actuating action which a user performs on the outer surface of the seat cover, namely at or in the outer surface portion of the specified actuation portion—as a result of which the touch-sensitive sensor surface is actuated, to provide a control signal. The user thus actuates the sensor surface of the control element by touching or tapping the outer surface of the seat cover in the actuation portion, for example. The control signal is provided based on the actuating action or based on the actuation of the sensor surface. In this case, the sensor surface and the actuation portion are so sensitive that successful actuation of the sensor surface occurs even if a user touches the sensor surface or the outer surface portion of the actuation portion with a gloved finger or executes the actuating action on the sensor surface or on the outer surface portion of the actuation portion.

For the motor vehicle, it holds true that the control device thereof is configured to accept the control signal provided by means of the control element. When the motor vehicle is finished or produced ready for use, the control device and the electronic control element are thus coupled or able to be coupled to one another at least to the extent that performing the actuating action involves controlling a vehicle function.

The actuation portion and a remaining portion of the seat cover—in particular the actuation portion and the non-actuation portion directly adjacent thereto or directly adjoining thereto—are connected to one another without gaps. In this case, both the actuation portion and the non-actuation portion may each be flexurally slack. They may be flexurally slack irrespective of whether or not the outer surface portion of the actuation portion is formed by the sensor surface of the control element. At least the non-actuation portion of the seat cover may be single-part or multi-part and/or single-layered or multi-layered. In this case, the individual parts or layers—if present—are connected to one another in a force-fitting, form-fitting and/or materially bonded manner, for example sewn, riveted, screwed, adhesively bonded, etc. to one another. A leather or a leather-like material or another seat cover material, for example, are considered as the material for the outermost layer of the seat cover.

Since the seat cover is formed by the actuation portion and the remaining portion or non-actuation portion connected thereto without gaps, there is no gap on the outside of the seat body and, in consequence, on the outside of the seat element. The seat cover is placed or tensioned continuously over the seat body (and over the possibly present padding material), thus resulting in a closed outer surface of the seat element. The control element therefore fits particularly esthetically into the overall appearance of the seat element. It is therefore possible to omit producing a panel (as in the case of conventional operator control elements), which is reflected in an advantageously particularly simple structure of the seat element and in a particularly mass-efficient construction of the seat element, that is to say one with few components. In addition, some process steps can be omitted in the production of the seat element, for example the fixing of an operator control element in the panel, handling and alignment of the panel on a conventional support element, fixing of the panel to this support element, etc. Corresponding connecting means, such as adhesive means, screw elements and the like, are also dispensed with, which is why the seat element and the accordingly equipped motor vehicle, in particular motorcycle, can be produced particularly economically efficiently. The outer surface without gaps also ensures that no liquid, for example rainwater, penetrates the interior of the seat element.

The control element is designed, in particular, to be free of mechanically movable elements which would necessarily have to be moved in order to actuate the sensor surface. The control element thus differs from conventional buttons, switches, etc. in this way. The structure of the control element without movement mechanics prevents noise and consequently contributes to a particularly advantageous NVH quality (NVH: Noise, Vibrations, Harshness). In addition, a particularly simple structure of the control element with an advantageously particularly low number of components is produced, which as a result supports integration of the control element into the seat element in a manner efficient for installation space.

Electrical conductor elements, such as power supply cables, signal cables, etc., by means of which the control element is connected to the control device of the motor vehicle in the position fitted as intended, are integrated into the seat cover, in particular in a manner such that they cannot be identified optically without further aids and cannot be felt by the user. For example, the conductor elements are applied (for example vapor deposited, imprinted, etc.) onto a flat, flexurally elastic line carrier, wherein the line carrier is sewn or adhesively bonded to the seat cover. It is also conceivable that the conductor elements are directly incorporated, for example woven, sewn, etc., into a material of the seat cover. The conductor elements may also be arranged between two material layers of the seat cover.

In an alternative configuration, provision may be made in the position fitted as intended for one or more of the electrical conductor elements to be showing in an optically identifiable manner through the seat cover on the outer surface thereof or to be able to be felt at least through the outer surface. The respective conductor element visible/tangible at the outer surface may, for example, show as a design element, for instance as a relief, on the outer surface or may be arranged directly on the outer surface. It is conceivable, in particular, that the corresponding conductor element is applied, for example imprinted or vapor deposited, onto the outer surface or is sewn, etc. on the outside to the outer surface. In this case, a marking arrangement, which is described in more detail further below, may comprise the respective conductor element visible/tangible at the outer surface. In other words: the respective conductor element visible/tangible at the outer surface may function as a marking element of the marking arrangement.

In another possible embodiment of the seat cover, the first outer surface portion, that is to say the outer surface portion of the actuation portion, is formed by the control element, in particular by the sensor surface thereof. This means that the sensor surface is functionally assigned to the actuation portion by virtue of the sensor surface forming the outer surface portion of the actuation portion. In this case, the non-actuation portion and the sensor surface forming the outer surface portion of the actuation portion are thus assembled without gaps to form the overall outer surface of the seat cover and, in particular, are connected to one another in a force-fitting, form-fitting and/or materially bonded manner. This results in a particularly thin seat cover which can be used in a particularly versatile and flexible manner. In addition, the control element, in particular the sensor surface thereof, is integrated into an overall appearance of the seat cover in an esthetically particularly advantageous manner.

In an alternative development, the seat cover comprises a seat cover layer, the top side of which forms at least part of the outer surface portion of the actuation portion of the seat cover. As a result, the seat cover layer comprises the actuation portion. The sensor surface of the control element is in this case arranged, in particular fixed, opposite the actuation portion on a rear side of the seat cover layer located opposite the top side or outer surface of the seat cover layer. In the position of the control element fitted as intended, the sensor surface thereof is covered by the seat cover layer, effectively arranged underneath the seat cover layer. For example, the seat cover layer stretches over the sensor surface. If the user now touches the top side of the seat cover layer, for example they push it in, this actuates the (resistive) sensor surface arranged underneath the seat cover layer. In order to ensure actuation of the sensor surface through the seat cover layer itself, when the sensor surface is designed as a capacitive sensor surface, provision is furthermore made for the seat cover layer to be of electrically conductive design overall or at least in the actuation region. To this end, the seat cover layer may be formed of an electrically conductive material in full or may have at least material portions, for example threads or fibers, which are electrically conductive. The electrically conductive material or the electrically conductive material portions produce an electrical connection between the top side and the rear side of the seat cover layer such that the capacitive sensor surface can be actuated particularly effectively by the user. Regardless of whether the seat cover layer is electrically conductive or electrically isolating, the result is a closed, in particular seamless, outer surface of the seat cover without gaps.

Another possible embodiment makes provision for the remaining portion of the seat cover to be formed by an upholstery surface of upholstery, wherein the sensor surface and the upholstery surface terminate flush with one another and without gaps. The seat cover may thus comprise the upholstery or be formed by the upholstery. As a result, the entire outer surface of the seat cover is formed proportionally by the upholstery surface. The electronic control element may be embedded in the upholstery, wherein the sensor surface and the second outer surface portion, that is to say the outer surface portion of the non-actuation portion, form the entire outer surface of the seat cover without gaps and flush with one another. Examples of the material used for the upholstery and thus for at least a part of the seat cover may be a 3D-printed foam body, a closed-membrane integral foam, etc. Consequently, the seat cover can be used in a particularly versatile and flexible manner, in particular when the upholstery and a seat pan or a seat support are formed in one piece with one another, for example being produced by means of a single common generative production process. In general, the expression “seat cover” herein is accordingly also to be understood as meaning that the seat cover 1 may also be a final outermost layer of the seat element 2.

In yet another embodiment of the seat cover, it comprises a marking arrangement which corresponds positionally with the actuation portion. The marking arrangement is formed or arranged, in particular, on the outer surface of the seat cover (or where appropriate on the top side of the seat cover layer) and is fixed there in a force-fitting, form-fitting and/or materially bonded manner, for example sewn, adhesively bonded, welded, screwed, riveted, etc. As an alternative or in addition, it is conceivable that the outer surface of the seat cover (or the top side of the seat cover layer) is formed at least in part by the marking arrangement. The marking arrangement may accordingly be an integral component of the seat cover or the seat cover layer. The marking arrangement comprises one or more of the following marking elements:
a color marking,
an impression,
an embroidered structure,
a stitched structure,
a marking cover element,
a badge,
a light element.

Since the marking arrangement and the actuation portion correspond positionally with one another, that is to say in terms of their respective location, it is particularly simple for the user to find the sensor surface and to switch or to control the corresponding vehicle function(s). To this end, the at least one marking element provides a symbol which characterizes the corresponding vehicle function(s), for instance a symbol for a heating system function, in particular a seat heating system function, etc. Provided that the marking arrangement covers the outer side of the actuating portion, at least the portion of the marking arrangement which covers the actuation portion is designed so that the sensor surface can be actuated through the portion of the marking arrangement which covers the outer surface portion of the actuation portion when this portion of the marking arrangement is touched.

In another possible configuration, an actuation path is identified, that is to say emphasized or marked, on the outer surface portion, in particular on the outer surface portion of the actuation portion by the marking arrangement. Provision may be made, for example, for the control element to be designed to control a vehicle function which can be adjusted in several steps or without steps, for example the seat heating function, a dimmable illumination function, a fan function, etc. Intended or specified control gestures for adjusting corresponding intensities/steps of such a function may be using a fingertip to move along or sweep the elongate actuation path. In order for the user to be able to quickly find this elongate actuation path with particularly low effort and with particularly little distraction, a positional location of the actuation path is marked by the marking arrangement. In addition, the marking arrangement may be arranged along the entire actuation path so that the user can distinguish the actuation path easily from portions of the outer surface which do not interact with the control element. In order to give the user the opportunity to be able to feel the actuation path with particularly low effort without averting their gaze, the positional location of the actuation path can be identified by haptically acting (raised and/or sunken) marking elements.

According to one development of the seat cover, it comprises a checking device which is designed to use the actuation portion to provide the user with a checking signal which characterizes successful actuation of the sensor surface. The user thus obtains feedback if they have successfully carried out the actuating action. To this end, provision may be made for the checking device and the control element to be coupled or able to be coupled to one another, whereby the control element activates the checking device when the sensor surface is actuated successfully, subsequent to which the checking device outputs the checking signal. The checking signal may be haptic, optical and/or acoustic in nature. The checking device accordingly comprises an output unit which is designed to output or provide the checking signal, for instance a loudspeaker, a display screen, etc.

In another configuration, the checking device comprises a spring element which is suddenly deformed and, in the process, outputs a checking noise when the sensor surface is actuated and thus provides haptic feedback. To this end, the spring element is produced as a spring strip, for example made of spring steel, and is shaped so that it can be bent from a stable rest state via a metastable state to an unstable final state. Due to the effect of force, for example compression, the spring strip is thus bent from the stable rest state until it reaches the metastable state. If the spring strip is compressed beyond the metastable state, it produces a clicking noise as it suddenly changes to the unstable final state. If the force reduces again, the spring element automatically springs back from the unstable final state via the metastable state back to the stable rest state, which again produces the clicking noise. The spring element is arranged, in particular, in front of the sensor surface so that the user must bend the spring element or the spring strip into the unstable final state in order to operate the sensor surface. On the one hand, the user thus obtains, due to the clicking noise, acoustic confirmation that they have actuated the sensor surface. On the other hand, the user receives haptic feedback when the actuation of the sensor surface is successful since the change of the spring element from the metastable state to the unstable final state thereof is clearly noticeable.

Another option of implementing the spring element to provide the checking noise is to provide a material body, for instance made of an elastomer, which has hollow spaces (“bubbles”) through it and which is reversibly elastically deformable. In this case, the walls of the hollow spaces function as a respective spring element. When the material body is compressed, the hollow spaces of the hollow spaces are deformed so as to output the clicking noise-analogously to the above description.

The spring element manages without further electronic components, has a particularly easily implementable design and is particularly compact. It can therefore be integrated into the seat cover particularly efficiently. It also offers an advantageous possibility for the user to be provided with acoustic and optical feedback about the actuation of the sensor surface.

In another configuration, the checking device may comprise a light unit which is designed to output and/or to change a checking light signal based on actuation of the sensor surface. To this end, the light unit may comprise the light element. As an alternative or in addition to the light element, the light unit may comprise at least one further illuminant, for instance an LED; luminescent, illuminable fibers, threads or strands of fibers or threads; waveguide elements, etc. If the user actuates the sensor surface, for example, a first checking light signal is output via the checking device, that is to say via the light unit, the checking light signal communicating to the user that they have successfully actuated the sensor surface. Furthermore, provision may be made for an illuminant of the light unit which emits light even before the actuation is changed in terms of light intensity and/or light color due to successful actuation of the sensor surface. This is provided, in particular, for the case in which the illuminant of the checking device is the light element of the marking arrangement. The user can particularly quickly and easily identify while using the light unit whether the corresponding vehicle function is activated or deactivated. By evaluating the change in the checking light signal, the user can also easily identify with low effort at which stage/intensity the vehicle function is currently being operated. The light unit is fitted, in particular, in a region of the seat cover which can be identified or found particularly easily by the user. The user is then advantageously hardly distracted from their driving task when operating/controlling the vehicle function or checking a switching or level state of the vehicle function.

The invention also relates to a seat element for the motor vehicle, wherein the seat element comprises a seat body and a cover designed according to the previous description. In this case, the seat body is covered by the seat cover, as a result of which the seat element comprises the actuation portion for actuating the sensor surface of the control element on the outer surface of the seat cover.

The invention moreover relates to a motor vehicle, in particular a motorcycle, which is provided with a seat element designed according to the previous description. In the motor vehicle or motorcycle/motorbike, the electronic control element and the control device of the motor vehicle are coupled or able to be coupled to one another wirelessly or in a wired manner-possibly by means of an on-board power supply system of the motor vehicle—in order to control the vehicle function or vehicle functions.

The outer surface of the seat cover or of the seat element generally has a dual functionality, specifically is used on the one hand to protect elements of the seat body (upholstery, dimensionally stable support, fastening elements, etc.) from weather influences. On the other hand, the outer surface-specifically by means of the actuation portion-functions as an input element or operator control elements for controlling the vehicle function(s). The seat cover itself may furthermore comprise upholstery.

In addition, the invention relates to a method for controlling at least one vehicle function of a motor vehicle by means of a seat cover designed according to the previous description. In the method, a user executes or performs an actuating action on the outer surface portion of the specified actuation portion of the seat cover, which actuates the touch-sensitive sensor surface. A control signal, based on which the vehicle function is controlled, is provided to a control device of the motor vehicle by the control element based on the actuation of the sensor surface. The actuating action is, in particular, a touch input, for example a single tap or multiple taps, a swiping or stroking gesture, etc. The actuating action or touch input may in this case be input by means of one finger or by means of several fingers at the same time. Provision is made, in particular, for different vehicle functions to be subject to open-loop/closed-loop control depending on the actuating action and/or for the vehicle function to be subject to different open-loop/closed-loop control depending on the actuating action.

Other features of the invention may become evident from the claims, the figures and the description of the figures. The features and combinations of features cited in the description hereinabove and the features and combinations of features cited in the description of the figures hereinbelow and/or shown in the figures alone can be used not only in the particular indicated combination but also in other combinations or on their own without departing from the scope of the invention.

### BRIEF DESCRIPTION OF THE DRAWINGS

FIG. 1 is a schematic and sectioned view of a seat element which comprises a seat cover having an electronic control element;

FIG. 2 is a schematic and sectioned view of the seat element, wherein the seat cover comprises a seat cover layer, with which a sensor surface of the control element is covered; and

FIG. 3 is a schematic and sectioned view of the seat element, wherein the control element is partly embedded in upholstery.

### DETAILED DESCRIPTION OF THE DRAWINGS

The text below provides a joint description of a seat cover 1, a seat element 2 comprising the seat cover 1, and a motor vehicle (not illustrated) which comprises, in particular, a saddle seat system, and a method for controlling at least one vehicle function by means of the seat cover 1. In the figures, identical and functionally identical elements are provided with the same reference signs.

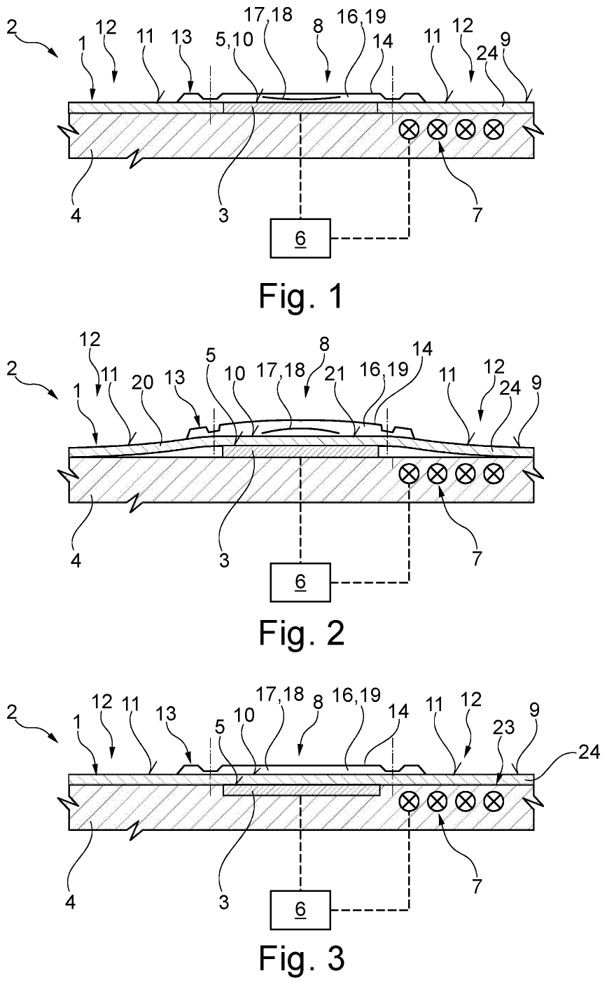

FIG. 1 shows a schematic and cutaway view of the seat element 2 which comprises the seat cover 1 having an electronic control element 3. In the position fitted as intended, a seat system, in particular a saddle seat system, of the motor vehicle or motorcycle or motorbike is formed by the seat element 2. This means that the motorbike comprises the seat element 2 and consequently the seat cover 1 as a constituent part of the seat system. In this case, the seat element 2 is, for example, the seat cushion or a backrest. Furthermore, the seat element 2 may be a saddle seat element which is straddled by a user of the corresponding seat system.

The seat cover 1 may comprise upholstery 4 and, in any case, comprises the electronic control element 3 which comprises a touch-sensitive, in the present case capacitive, sensor surface 5. In the position fitted as intended (that is to say when the motor vehicle or motorbike comprising the seat element 2 is produced ready for use), the control element 3 is connected wirelessly or in a wired manner to a control device 6 of the motor vehicle. The control device 6 is used to subject the vehicle function, in the present case using the example of a seat heating system 7, to open-loop and/or closed-loop control. To this end, the control device 6 and the seat heating system 7 are coupled to one another for the purpose of control signal transmission. The seat heating system 7 is designed to accept as input control signal a control signal which is provided or supplied by means of the control device 6.

The seat cover 1 comprises an actuation portion 8 such that the entire outer surface 9 of the seat cover 1 is formed by a first outer surface portion 10 of the actuation portion 8 and a second outer surface portion 11 of a remaining portion 12 or non-actuation portion 12 of the cover 1 which is different from the actuation portion 8. According to FIG. 1, in one possible exemplary embodiment, the first outer surface portion 10 of the actuation portion 8 is formed by the sensor surface 5.

By executing an actuating action which is performed by a user on/in the first outer surface portion 10, that is to say on/in the portion of the outer surface 9 of the seat cover formed by the actuation portion 8, for instance a single tap or multiple taps, stroking, swiping, etc., the user actuates the sensor surface 5 since the sensor surface 5 is functionally assigned to the actuation portion 8 of the seat cover 1. As a result of this, a control signal, based on which the vehicle function, for example the seat heating system 7, is controlled, is provided to the control device 6 of the motor vehicle by means of the control element 3 based on the user input. The seat cover 1 can thus be used in conjunction with the control element 3 to switch over the vehicle function (for instance the seat heating system 7) between an activated state and a deactivated state. An operating stage or intensity of the vehicle function (for example the seat heating system 7) can likewise be set by means of the seat cover 1 or by means of the control element 3.

FIG. 1 furthermore illustrates that the actuation portion 8 and the remaining portion 12 or non-actuation portion 12 of the seat cover 1 adjoin one another without gaps and, in particular, are connected to one another without gaps. In other words, the seat cover 1 is designed in such a way that the entire outer surface 9 thereof has no gaps.

In addition, FIG. 1 shows a marking arrangement 13 which corresponds positionally with the actuation portion 8. In the present case, this means that a positional location of the actuation portion 8 is identified/marked on the outer surface 9 of the seat cover 1 by the marking arrangement 13. This is because the marking arrangement 13 is arranged or formed on the outer surface 9 or at least partly forms the outer surface. In this case, the marking arrangement 13 comprises one or more of the following marking elements 14: a color marking, an impression, an embroidered structure, a stitched structure, a marking cover element (which differs optically and/or haptically from the seat cover element), etc. In the present case, the marking arrangement 13 comprises a flexible or flexurally slack or rigid badge 15 which is connected in a force-fitting, form-fitting and/or materially bonded manner to the outer surface 9. Provision may be made, for example, for the badge 15 to be welded, riveted, sewn, adhesively bonded, etc. to the outer surface 9 of the seat cover 1. In addition, the marking arrangement 13 may comprise a light element 16 (for example an LED, an electroluminescent sheet, an optical fiber, a lighting thread, etc.). The light element 16 may be in the form of an active electrical and/or electronic component or a component which emits light passively (for example a phosphorescent or fluorescent element).

The marking arrangement 13 can be used to haptically and/or optically emphasize or mark an elongate actuation path (not illustrated) along which the user runs their finger or fingertip-so as to touch the first outer surface portion 10. In other words: if a swiping or stroking gesture of the user is considered for open-loop/closed-loop control of the vehicle function, the path along which the swiping or stroking gesture is to be performed in order to subject the vehicle function to open-loop/closed-loop control can be emphasized by means of the marking arrangement 13, in particular by way of the light element 16.

The seat cover 1 also comprises a checking device 17 by means of which a checking signal characterizing successful actuation of the sensor surface 5 is provided to the user via the actuation portion. In this case, the checking device 17 may be at least partly integrated into the marking arrangement 13. In the present example, the checking device 17 comprises a spring element 18 which is designed as a snap-action disk and outputs a checking noise when the sensor surface 5 is actuated and thus provides the user with haptic and optical feedback. In an alternative configuration (not illustrated in the figures), the spring element 18 may be formed by elastically reversible deformable walls of hollow spaces, which pass through a material body, for instance made of an elastomer, for example a material body of the marking arrangement 13. When the material body is compressed, the walls of the hollow spaces are deformed so as to output the clicking noise.

The checking device 17 furthermore comprises in the present case a light unit 19 which outputs a checking light signal based on actuation of the sensor surface 5 or changes an existing checking light signal. In this case, provision may be made for the light unit 19 to comprise the light element 16 as at least one illuminant.

FIG. 2 shows a schematic and cutaway view of the seat element 2, wherein the seat cover 1 comprises a seat cover layer 20 which covers the sensor surface 5 of the control element 3. The seat cover layer 20 comprises a top side 21 and a rear side 22 which face away from one another and are spaced apart from one another by a height/thickness of the seat cover layer 20. At least the first outer surface portion 10 of the seat cover 1 is formed by the top side 21. In this case, the seat cover layer 20 is electrically conductive in the actuation portion 8 such that an electrically conductive connection is established between at least one portion of the top side 21 arranged in the actuation portion 8 and a portion of the rear side 22 arranged in the actuation portion 8. In this case, the sensor surface 5 adjoins the rear side 22 in the actuation portion 8—in the present case directly—and is in particular fixed thereto. The user can thus actuate the sensor surface 5 through the seat cover layer 20, that is to say can set or operate the vehicle function, in particular the seat heating system 7, through the seat cover layer 20 as desired. The electronic control element 3 is accordingly covered or spanned by the seat cover layer 20 to the extent that the sensor surface 5 is covered by the seat cover layer 20. The result is advantageously a structure of the outer surface 9 which has no gaps, in particular has no seams, and which is formed in this case by the seat cover layer 20.

FIG. 3 shows a schematic and cutaway view of the seat element 2, wherein the control element 3 is partly embedded in the upholstery 4. This results in a particularly flat shape of the seat cover 1. The upholstery 4 may be upholstery of the seat element 2. In the present case, the upholstery 4 is a component part of the seat cover 1.

FIG. 3 is used as a basis to explain a further embodiment in which the remaining portion 12 of the seat cover 1 is formed by an upholstery surface 23 of the upholstery 4, wherein the sensor surface 5 and the upholstery surface 23 terminate flush with one another and without gaps. This means that a cover material layer 24, for example leather, artificial leather, textile, etc., which is arranged on the upholstery 4 and is illustrated only by way of example, may be omitted, in contrast to the other embodiments if they comprise a cover material layer 24 of this type. In this case, the entire outer surface 9 of the seat cover 1 is formed by the upholstery surface 23. In this respect, the expression “seat cover” should also be understood generally here as meaning that the seat cover 1 may be a final outermost layer of the seat element 2.

Overall, the seat cover 1, the seat element 2 and the motor vehicle or motorbike show a respective possibility of integrating an operator control element (in the present case the control element 3) for controlling a vehicle function (for example the seat heating system 7) particularly efficiently into a seat system system of the vehicle, in particular the motorbike or the car. In this case, the first outer surface portion 10 may face upward, to the right, to the left or downward in relation to a motor vehicle parked on the ground as intended. It should also be understood that the motor vehicle may comprise at least one other seat element 2. In this case, the respective seat element 2 may comprise at least one other control element 3.

A conventional transition between a conventional switch device and the outer surface 9 of the seat cover 1 is avoided as desired by the invention. In particular, an extra panel made from plastic or a switch console made from plastic—in each case generally in the form of a complicated, black and grained injection molded component—is dispensed with. A complicated precisely fitting orientation of such a plastics component is advantageously omitted. Component edges protruding over the seat cover 1, and holes and gaps between the panel and the outer surface 9 are likewise avoided, as is (for example aging-induced) distortion/deformation of the panel. Owing to the seat cover 1 which now has, the operator control functionality for operator control of the at least one vehicle function by means of the control element 3 fits particularly favorably into the overall image of the motorbike bench seat.

Thin, flat conductor tracks and capacitive signals are used for switching or controlling the vehicle function, in particular the seat heating system 7. The signals are processed by a central vehicle electronics system, in particular by means of the control device 6, and are evaluated and processed further for switching/controlling the seat heating system 7. The conductor tracks and capacitive receiver elements, in particular the sensor surface 5, are integrated into the seat cover 1 so as to be invisible. In order to provide the motorcycle rider with haptic feedback as well, there is a need for palpable/tangible elements which are realized in the present case by haptically acting—that is to say raised and/or sunken-marking elements 14. The spring element 18 can be used for particularly highly palpable haptic feedback (similar to a clicker). This provides a possibility for the haptic feedback to be provided reliably to the rider even through thick protective motorcycle clothing, such as gloves. In the case of appropriate visibility, elements which illuminate actively or passively and are applied or sewn to the outer surface 9 of the seat cover 1 are also possible. The rider can therefore be provided with optical feedback about the switching state of the vehicle function or seat heating system 7.

### LIST OF REFERENCE SIGNS

1 Seat cover
2 Seat element
3 Electronic control element
4 Upholstery
5 Sensor surface
6 Control device
7 Seat heating system
8 Actuation portion
9 Outer surface
10 First outer surface portion
11 Second outer surface portion
12 Non-actuation portion/remaining portion of the seat cover
13 Marking arrangement
14 Marking element
15 Badge
16 Light element
17 Checking device
18 Spring element
19 Light unit
20 Seat cover layer
21 Top side
22 Rear side
23 Upholstery surface
24 Cover material layer

1.-11. (canceled)

12. A seat cover for a seat element of a motor vehicle, comprising:
an electronic control element having a touch-sensitive sensor surface, which control element is configured to be coupled to a control device of the motor vehicle for controlling a vehicle function; and
an outer surface portion of a predetermined actuation portion of the seat cover, wherein an actuating action which a user performs on the outer surface portion of the predetermined actuation portion actuates the touch-sensitive sensor surface to provide a control signal,
wherein the predetermined actuation portion and a remaining portion of the seat cover are connected to one another without gaps.

13. The seat cover according to claim 12, wherein
the outer surface portion of the actuation portion is formed by the sensor surface.

14. The seat cover according to claim 12, further comprising:
a seat cover layer, wherein
a top side of the seat cover layer forms the outer surface portion of the actuation portion,
the seat cover layer is electrically conductive in the actuation portion, and the sensor surface is arranged opposite the actuation portion on a rear side of the seat cover layer located opposite the top side.

15. The seat cover according to claim 12, wherein
the remaining portion of the seat cover is formed by an upholstery surface of upholstery, and
the sensor surface and the upholstery surface terminate flush with one another and without gaps.

16. The seat cover according to claim 12, further comprising:
a marking arrangement which corresponds positionally with the actuation portion and which comprises one or more of the following marking elements:
a color marking,
an impression,
an embroidered structure,
a stitched structure,
a marking cover element,
a badge, or
a light element.

17. The seat cover according to claim 16, wherein
an actuation path is identified on the outer surface portion by the marking arrangement.

18. The seat cover according to claim 12, further comprising:
a checking device which is configured to use the actuation portion to provide a checking signal which characterizes successful actuation of the sensor surface.

19. The seat cover according to claim 18, wherein
the checking device comprises a spring element which outputs a checking noise when the sensor surface is actuated and, in the process, provides haptic feedback.

20. The seat cover according to claim 18, wherein
the checking device comprises a light unit which is designed to output and/or to change a checking light signal based on actuation of the sensor surface.

21. A seat element for a motor vehicle, comprising:
a seat cover according to claim 12; and
upholstery which is covered with the seat cover.

22. A motor vehicle, comprising:
a seat element according to claim 21; and
the control element,
wherein the electronic control element and the control device of the motor vehicle are coupled to one another in order to control a vehicle function.
